(19) United States
(12) Patent Application Publication
(10) Pub. No.: US 2025/0324578 A1
(43) Pub. Date: Oct. 16, 2025

(54) MEMORY DEVICE, FORMING METHOD THEREOF AND MEMORY SYSTEM

(71) Applicant: YANGTZE MEMORY TECHNOLOGIES CO., LTD., Wuhan (CN)

(72) Inventors: Xu HOU, Wuhan (CN); Shouchun PENG, Wuhan (CN)

(21) Appl. No.: 18/796,819

(22) Filed: Aug. 7, 2024

(30) Foreign Application Priority Data
Apr. 10, 2024 (CN) 2024104315150

(51) Int. Cl. H10B 12/00; G11C 11/408; G11C 11/4091; H01L 25/00; H01L 25/065; H01L 25/18; H10B 80/00

(52) U.S. Cl. CPC H10B 12/50; G11C 11/4085; G11C 11/4087; G11C 11/4091; H01L 25/0657; H01L 25/18; H01L 25/50; H10B 80/00

(57) ABSTRACT

The present application provides a memory, a forming method of the memory and a memory system. The memory includes a first semiconductor structure and a second semiconductor structure coupled with the first semiconductor structure. The first semiconductor structure includes a memory array, word lines and bit lines; wherein the memory array includes memory banks each including memory blocks; the word lines and bit lines are coupled with the memory blocks, a length direction of the word lines is a first direction, a length direction of the bit lines is a second direction perpendicular to the first direction. The second semiconductor structure includes word line drivers corresponding to each memory block respectively, the word line drivers being coupled with the word lines; the word line driver includes transistors arranged in a channel width direction of the transistor. The channel width direction of the transistor is perpendicular to the first direction.

### CROSS-REFERENCE TO RELATED APPLICATIONS

The present application claims priority to Chinese Patent Application No. 2024104315150, which was filed Apr. 10, 2024, is titled “MEMORY DEVICE, FORMING METHOD THEREOF AND MEMORY SYSTEM,” and is hereby incorporated herein by reference in its entirety.

### TECHNICAL FIELD

The present application pertains to the field of semiconductor chip technology, and particularly relates to a memory, a forming method thereof and a memory system.

### BACKGROUND

As technology develops, new production processes are developed continuously in the field of semiconductor industry, and memories are advancing towards larger memory capacity, faster read/write speed and smaller size.

### SUMMARY

In a first aspect, a memory is provided. The memory includes a first semiconductor structure and a second semiconductor structure, the first semiconductor structure being coupled with the second semiconductor structure. The first semiconductor structure includes a memory array, word lines and bit lines; wherein the memory array includes a plurality of memory banks each including a plurality of memory blocks; the word lines and bit lines are coupled with the memory blocks, a length direction of the word lines is a first direction, a length direction of the bit lines is a second direction, and the first direction is perpendicular to the second direction. The second semiconductor structure includes a plurality of word line drivers corresponding to each memory block respectively, the word line drivers being coupled with the word lines; the word line driver includes a plurality of transistors arranged in a channel width direction of the transistor. The channel width direction of the transistor is perpendicular to the first direction.

In some implementations, the number of the word line drivers is N and the N word line drivers are arranged in the first direction.

In some implementations, the N word line drivers are arranged into one row of word line drivers in the first direction.

In some implementations, the N word line drivers are arranged into two rows of word line drivers in the first direction, the two rows of word line drivers are arranged in the second direction.

In some implementations, the word line drivers comprise odd-numbered word line drivers and even-numbered word line drivers, wherein the odd-numbered word line drivers are disposed on a side of a corresponding memory block in the first direction, and the even-numbered word line drivers are disposed on another side of the corresponding memory block in the first direction.

In some implementations, the second semiconductor structure further comprises decoders; a sum of lengths of the plurality of odd-numbered word line drivers and the decoders in the second direction is smaller than a length of the memory block in the second direction, and a sum of lengths of the plurality of even-numbered word line drivers and the decoders in the second direction is smaller than a length of the memory block in the second direction.

In some implementations, the second semiconductor structure further comprises sense amplifiers coupled with the bit lines; the sense amplifiers comprise odd-numbered sense amplifiers and even-numbered sense amplifiers, wherein the odd-numbered sense amplifiers are disposed on a side of the corresponding memory block in the second direction, and the even-numbered sense amplifiers are disposed on another side of the corresponding memory block in the second direction.

In some implementations, the first semiconductor structure and the second semiconductor structure are bonded.

In a second aspect, a forming method of a memory is provided. The method includes: forming a first semiconductor structure including a memory array, word lines and bit lines; wherein the memory array includes a plurality of memory banks each including a plurality of memory blocks; the word lines and bit lines are coupled with the memory blocks, a length direction of the word lines is a first direction, a length direction of the bit lines is a second direction, and the first direction is perpendicular to the second direction; forming a second semiconductor structure, wherein the second semiconductor structure comprises a plurality of word line drivers corresponding to each memory block respectively; the word line driver comprises a plurality of transistors arranged in a channel width direction of the transistor; and bonding the first semiconductor structure and the second semiconductor structure, wherein the channel width direction of the plurality of transistors in the word line drivers is perpendicular to the first direction.

In some implementations, the number of the word line drivers is N and the N word line drivers are arranged in the first direction.

In some implementations, the N word line drivers are arranged into one row of word line drivers in the first direction.

In some implementations, the N word line drivers are arranged into two rows of word line drivers in the first direction, the two rows of word line drivers are arranged in the second direction.

In some implementations, the word line drivers comprise odd-numbered word line drivers and even-numbered word line drivers, wherein the odd-numbered word line drivers are disposed on a side of a corresponding memory block in the first direction, and the even-numbered word line drivers are disposed on another side of the corresponding memory block in the first direction.

In some implementations, the second semiconductor structure further comprises decoders; a sum of lengths of the plurality of odd-numbered word line drivers and the decoders in the second direction is smaller than a length of the memory block in the second direction, and a sum of lengths of the plurality of even-numbered word line drivers and the decoders in the second direction is smaller than a length of the memory block in the second direction.

In some implementations, the second semiconductor structure further comprises sense amplifiers coupled with the bit lines; the sense amplifiers comprise odd-numbered sense amplifiers and even-numbered sense amplifiers, wherein the odd-numbered sense amplifiers are disposed on a side of the corresponding memory block in the second direction, and the even-numbered sense amplifiers are disposed on another side of the corresponding memory block in the second direction.

In some implementations, the first semiconductor structure is formed on a first wafer, and the second semiconductor structure is formed on a second wafer; bonding the first semiconductor structure and the second semiconductor structure comprises: bonding the first wafer and the second wafer and cutting the first wafer and the second wafer.

In a third aspect, a memory system is provided. The memory system includes a memory controller and the memory of any of the first aspect, the memory controller being coupled with the memory; the memory controller being configured to control the memory.

### BRIEF DESCRIPTION OF THE DRAWINGS

In order to explain the technical solutions in the present application more clearly, accompanying drawings required in some examples of the present application will be described in brief below. It is obvious that the drawings described below are only drawings of some examples of the present application and other drawings may be obtained according to these drawings for those of ordinary skill in the art. Furthermore, accompanying drawings described below may be regarded as illustrative diagrams rather than limiting the practical sizes of products, practical flows of methods and practical timings of signals involved in examples of the present application.

FIG. 1 is a circuit structure diagram of a memory provided in an example of the present application;

FIG. 2 is a structure diagram of a memory array provided in an example of the present application;

FIG. 3 is a circuit structure diagram of a memory block provided in an example of the present application;

FIG. 4 is a circuit structure diagram of a memory cell provided in an example of the present application;

FIG. 5 is a diagram of the coupling relationship between a peripheral circuit and corresponding memory block as provided in an example of the present application;

FIG. 6 is a circuit structure diagram of a word line driver provided in an example of the present application;

FIG. 7 is a layout diagram of a word line driver provided in an example of the present application;

FIG. 8 is a first layout diagram of a peripheral circuit provided in an example of the present application;

FIG. 9 is a first layout diagram of a plurality of word line drivers provided in an example of the present application;

FIG. 10 is a structure diagram of a memory system provided in an example of the present application;

FIG. 11 is a physical structure diagram of a memory provided in an example of the present application;

FIG. 12 is a second layout diagram of a peripheral circuit provided in an example of the present application;

FIG. 13 is a second layout diagram of a plurality of word line drivers provided in an example of the present application;

FIG. 14 is a third layout diagram of a plurality of word line drivers provided in an example of the present application;

FIG. 15 is a third layout diagram of a peripheral circuit provided in an example of the present application;

FIG. 16 is a flow diagram of a forming method of a memory as provided in an example of the present application.

Reference numbers: 100. Memory (memory device); 110. first semiconductor structure; 120. second semiconductor structure; 200. memory array; 210. memory bank; 211. memory block; 220. memory cell; 221. capacitor; 222. array transistor; 300. periphery circuit; 310. word line driver; 311. odd-numbered word line driver; 312. even-numbered word line driver; 320. sense amplifier; 321. odd-numbered sense amplifier; 322. even-numbered sense amplifier; 330. decoder; 400. sub-word line driver; 410. first transistor; 420. second transistor; 430. third transistor; 500. memory system; 510. memory controller; 520. NAND memory.

### DETAILED DESCRIPTION

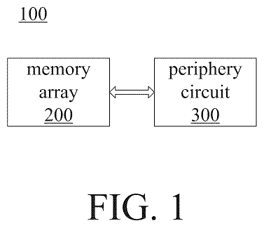

The technical solution in examples of the present application will be described below clearly and completely with reference to FIGS. 1-16. However, it is obvious that the described examples are only partial examples rather than all examples of the present application. All other examples obtained by one of ordinary skill in the art based on examples provided in the present application fall within the scope of the present application.

Unless otherwise stated in context, the term “include” will be interpreted as a meaning of open and containing, namely “contain but not limited to” throughout the description and claims. In the description of the specification, terms such as “one example”, “some examples”, “example implementation”, “illustratively” or “some implementations” are intended to indicate certain features, structures, materials or characteristics related to the example(s) or implementation(s) are included in at least one example or implementation of the present application. The illustrative representation of the above terms does not necessarily refer to the same example or implementation. Furthermore, the particular features, structures, materials or characteristics may be included in any suitable way in any one or more examples or implementations.

Here in below, terms such as “first”, “second” etc. are only used for description rather than being interpreted as indicating or implying relative importance or implicitly indicating the number of the referenced technical features. Therefore, a feature defined by “first” or “second” may include explicitly or implicitly one or more instances of the feature. In the description of examples of the present application, “a plurality of” means two or more unless otherwise specified.

While describing some examples, expressions such as “couple” as well as their extensions may be used. As an example, the term “couple” may be used while describing some examples to indicate that two or more components are in direct physical contact or electrical contact. In such a case, “couple” may also be described as “connect”. In addition, the term “couple” may also indicate there is no direct contact between the two or more components, but they still cooperate or interact with each other. Examples disclosed herein are not necessarily limited to the contents provided herein.

The use of “configured to” herein implies the wording has a meaning of open and inclusive, which does not exclude apparatuses adapted to or configured to execute additional tasks or steps.

Dynamic random access memory (DRAM) is a volatile memory device. FIG. 1 illustrates a structure diagram of a dynamic random access memory (referred to as memory 100 for short hereinafter). As shown in FIG. 1, the memory 100 (e.g.: memory device) may include a memory array 200 and a peripheral circuit 300 coupled with the memory array 200.

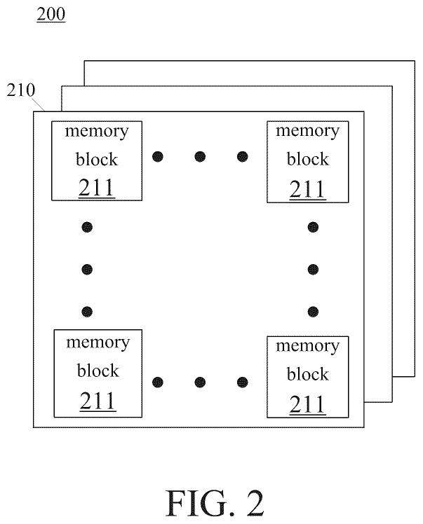

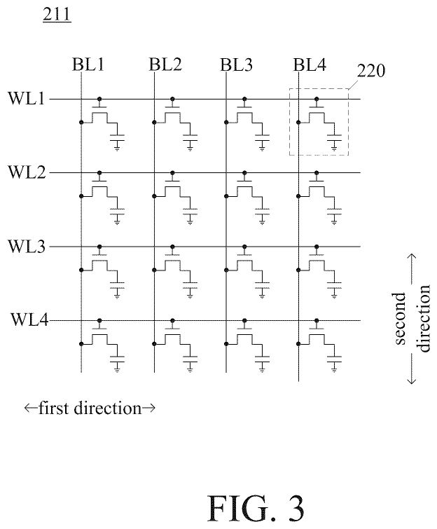

As shown in FIG. 2, the memory array 200 includes a plurality of memory banks 210, and each memory bank 210 may include a plurality of memory blocks 211. As shown in FIG. 3, a memory block 211 includes a plurality of memory cells 220. In some examples, a row of memory cells 220 may be coupled with a same word line in a first direction, and a column of memory cells may be coupled with a same bit line in a second direction. The first direction is a length direction of the word line, the second direction is a length direction of the bit line, and the first direction is perpendicular to the second direction.

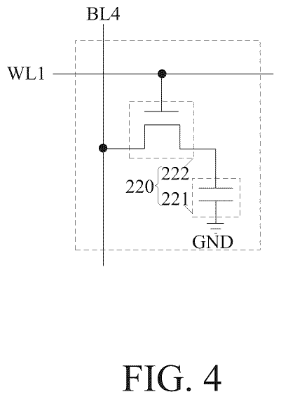

As shown in FIGS. 3 and 4, in some implementations, each memory cell 220 may include a capacitor 221 and an array transistor 222. An end of the capacitor 221 is connected to ground GND (or coupled with a node of fixed point potential) and the other end is coupled with a drain of the array transistor 222. A source of the array transistor 222 is coupled with the bit line (BL), and a gate of the array transistor 222 is coupled with the word line (WL).

When the array transistor 222 is turned on, the capacitor 221 may be charged or discharged. Whether data stored in the memory cell 220 is “1” or “0” is represented according to the charge amount stored in the capacitor 221 or the voltage difference across the capacitor 221.

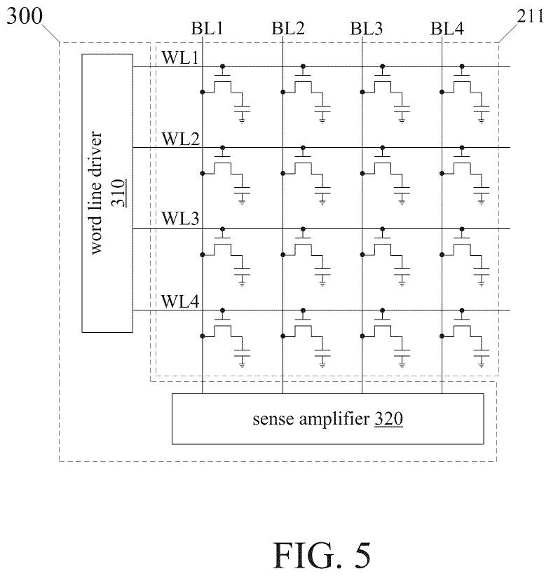

As shown in FIG. 5, in some implementations, the peripheral circuit 300 may include a plurality of word line drivers (WL drivers) 310 and sense amplifiers (SA) 320 corresponding to each memory block 211; wherein the word line drivers 310 are coupled with the memory cells through the word line, and the sense amplifiers 320 are coupled with the memory cells 220 through the bit line.

In a writing operation, the word line drivers 310 may select to apply a word line driving voltage Vpp to a word line, thereby turning on the array transistor 222 coupled with the word line. At this time, the capacitor 221 is charged by applying a high voltage to the bit line, thereby the capacitor 221 stores charges. And the capacitor 221 is discharged by applying a low voltage, such as ground voltage Vss, to the bit line, thereby the capacitor 221 discharges charges.

In a reading operation, the word line drivers 310 may select to apply a word line driving voltage Vpp to a word line, thereby turning on the array transistor 222 coupled with the word line such that the sense amplifier 320 can sense the voltage on the capacitor 221 via the bit line. In some examples, if the capacitor 221 stores sufficient charges, the sense amplifier 320 can sense a larger voltage, and data “1” is read out by comparing to a reference voltage; and if the capacitor 221 stores less or even no charge, the sense amplifier 320 can sense a lower voltage or even no voltage, and data “0” is read out by comparing to the reference voltage. In some other examples, the capacitor 221 storing sufficient charges indicates that the memory cell 220 stores data “0”, and the capacitor 221 storing less charges or even no charge indicates that the memory cell 220 stores data “1”.

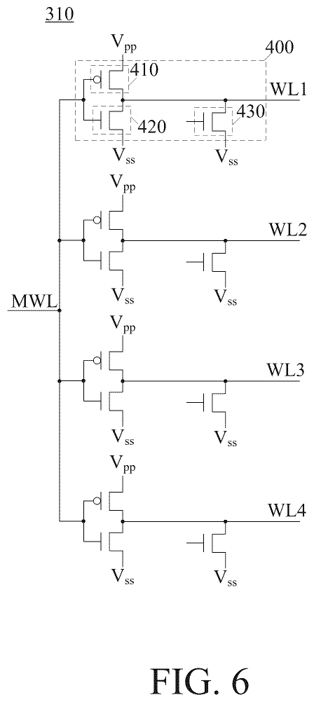

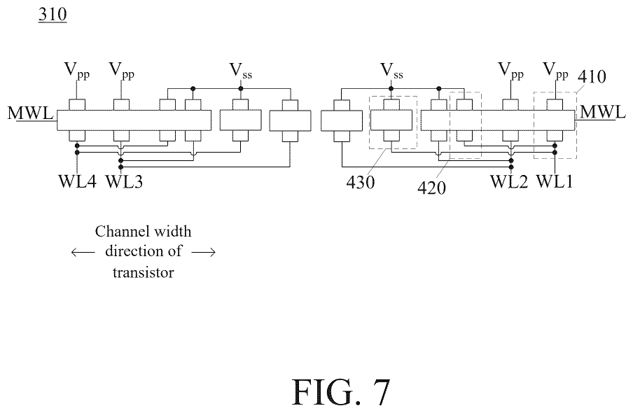

FIG. 6 illustrates a circuit structure diagram of a word line driver 310. As shown in FIG. 6, the word line driver 310 is coupled with a main word line (MWL) and a plurality of word lines respectively. The word line driver 310 may include a plurality of sub-word-line drivers 400 each coupled with the main word line and word lines in one-to-one correspondence respectively. Each sub-word-line driver may include a word line driver 310, wherein the first transistor 410 and the second transistor 420 are two transistors of different conductivity types such as P-channel transistor and N-channel transistor. In some implementations, the arrangement diagram of transistors in the word line driver 310 shown in FIG. 6 may be as shown in FIG. 7. As shown in FIG. 7, transistors in the word line driver 310 are arranged in the channel width direction (third direction) of the transistor.

As shown in FIGS. 6 and 7, the main word line is coupled with control ends of the first transistor 410 and the second transistor 420 respectively. A second end of the first transistor 410, a first end of the second transistor 420 and a first end of the third transistor 430 are coupled and coupled with the word line corresponding to the sub-word-line driver 400. A first end of the first transistor 410 is configured to input the word line driving voltage Vpp, a second end of the second transistor 420 and a second end of the third transistor 430 are configured to input the ground voltage Vss, and the control end of the third transistor 430 is configured to input corresponding word line control signals.

States of the first transistor 410 and the second transistor 420 are controlled by signals on the main word line and state of the third transistor 430 is controlled by the word line control signal. The sub-word-line driver 400 may apply a word line driving voltage Vpp or a ground voltage Vss to the corresponding coupled word line.

In some examples, when the second transistor 420 is in on state and the first transistor 410 is in off state, the plurality of sub-word-line drivers 400 in the word line driver 310 apply the ground voltage Vss to the corresponding coupled word lines, such that the plurality of word lines coupled with the word line driver 310 are kept in unselected state. When the first transistor 410 is in on state and the second transistor 420 is in off state, the third transistor 430 in one sub-word-line driver 400 is controlled to be in off state such that the sub-word-line driver 400 applies the word line driving voltage Vpp to the corresponding coupled word line; and the third transistors 430 in other sub-word-line drivers 400 are controlled to be in on state to pull down the voltages by the third transistors 430, such that other sub-word-line drivers 400 apply the ground voltage Vss to the corresponding coupled word lines. One word line coupled with the word line driver 310 is in selected state, and other word lines coupled with the word line driver 310 are kept in unselected state.

It should be understood that the peripheral circuit 300 may further include other circuit structures not shown in FIG. 5, such as a command decoder, a control logic circuit and a voltage generating circuit etc. The command decoder may receive commands (CMD) from the memory controller 510 and may decode the received commands. For example, commands may include such as write command (WR), read command (RD), active command (ACT) and pre-charge command (PRE) etc. The control logic circuit may control the voltage generating circuit, the word line drivers 310, the sense amplifiers 320 etc. based on the decoding results from the command decoder to implement active, read, write, pre-charge operations. It is not limited thereto in implementations and less or more circuit structures may be included. Further, since examples of the present application have not made improvements to these structures, these structures should not be interpreted as limitations to the present application, rather, it is only one implementation, and these structures may take other circuit forms in some other implementations.

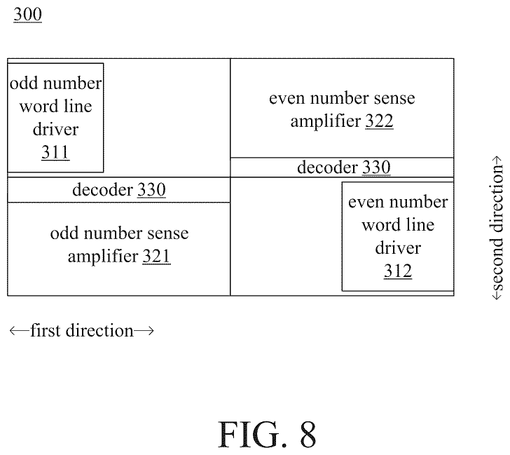

In some implementations, the peripheral circuit 300 and the memory array 200 are of the same size in plane, and the peripheral circuit 300 may be disposed under the memory array 200 to facilitate reducing the plane size of the memory 100. As shown in FIG. 8, in some implementations, the word line drivers 310 include odd-numbered word line drivers 311 and even-numbered word line drivers 312, and the sense amplifiers 320 include odd-numbered sense amplifiers 321 and even-numbered sense amplifiers 322. The odd-numbered word line driver 311 is disposed on one side of corresponding memory block 211 in a first direction, i.e., a length direction of the word line, and the even-numbered word line driver 312 is disposed on the other side of the corresponding memory block 211 in the first direction, i.e., the length direction of the word line. The odd-numbered sense amplifier 321 is disposed on one side of the corresponding memory block 211 in a second direction, i.e., a length direction of the bit line, and the even-numbered sense amplifier 322 is disposed on the other side of the corresponding memory block 211 in the second direction, i.e., the length direction of the bit line. Decoders 330 are disposed between the odd-numbered word line driver 311 and the odd-numbered sense amplifier 321, and between the even-numbered word line driver 312 and the even-numbered sense amplifier 322 respectively.

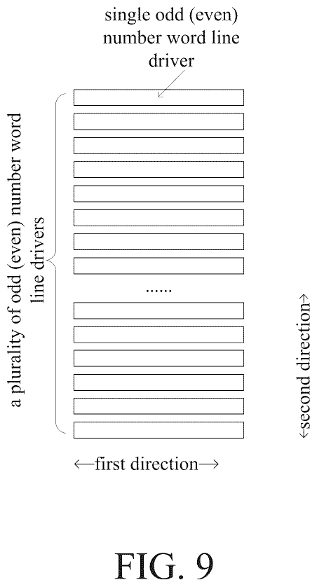

As described above, the peripheral circuit 300 includes a plurality of word line drivers 310 corresponding to each memory block 211. FIG. 9 illustrates arrangement diagram of the plurality of word line drivers 310. As shown in FIG. 9, in some implementations, a channel width direction of the transistor in each odd-numbered word line driver 311 (even-numbered word line driver 312) is parallel to the first direction, i.e., the length direction of the word line, and the plurality of odd-numbered word line drivers 311 (even-numbered word line drivers 312) are arranged in the second direction, i.e., the length direction of the bit line. Since the number of word lines coupled with each memory block 211 is large, a length of the plurality of odd-numbered word line drivers 311 (even-numbered word line drivers 312) corresponding to each corresponding memory block 211 in the second direction (i.e., the length direction of the bit line) is much greater than a length in the first direction (i.e., the length direction of the word line).

Since a length of the plurality of word line drivers 310 corresponding to each corresponding memory block 211 in the second direction (i.e., the length direction of the bit line) is much greater than a length in the first direction (i.e., the length direction of the word line), the design difficulty of the sense amplifiers 320 is increased. At the same time, the size of the memory block 211 in the second direction (i.e., the length direction of the bit line) is also increased such that the length of the bit line coupled with the memory block 211 is also increased, resulting in an increased coupling capacitance between bit lines, such that the array transistor 222 in the memory cell 220 may suffer relatively high leakage current and influence the read/write performance of the memory 100.

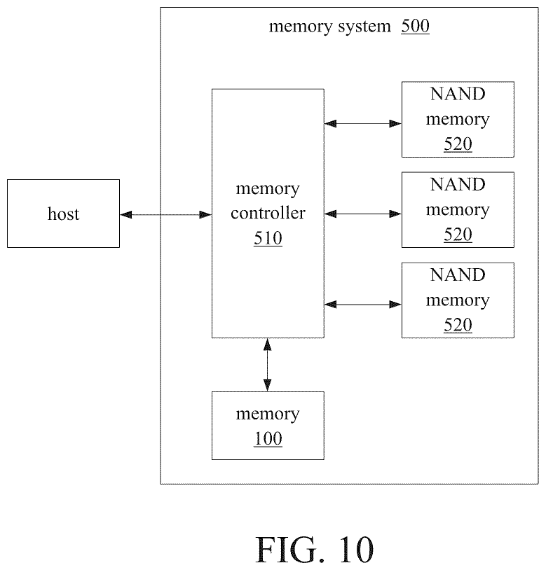

An implementation of the present application provides a memory system. As shown in FIG. 10, the memory system 500 includes a memory controller 510 and a memory 100, the memory controller 510 being coupled with the memory 100. The memory system 500 can be applied to and packaged in different types of electronic products such as a mobile phone (e.g., a handset), a desktop computer, a tablet, a notebook computer, a server, an on-vehicle device, a gaming console, a printer, a positioning device, a wearable device, a smart sensor, a mobile power source, a virtual reality (VR) device, an argument reality (AR) device, and servers or any other suitable electronic devices that can store data. In some examples, the memory system 500 may be a solid state drive (SSD), the memory 100 is a DRAM memory, and the memory system 500 may further include a NAND memory 520. The memory controller 510 is coupled with the memory 100 and the NAND memory 520 respectively.

In some implementations, the NAND memory 520 is configured to store data such as user data. The memory 100 is configured to store the logic to physical (L2P) mapping table. The memory controller 510 may communicate with an external device such as a host via at least one of various interface protocols. The interface protocols may include at least one of a universal serial bus (USB) protocol, a multi-media card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol.

The memory controller 510 is configured to receive data read command or data write command from the host and implement data read operation or data write operation on the NAND memory 520 according to the received data read command or data write command. In some examples, after the memory controller 510 receives a data read command from the host, the memory controller 510 transmits a physical address search request to the memory 100 which includes the logical address of the host. The memory 100 searches for the physical address of the NAND memory 520 in the L2P mapping table using the logical address of the host and transmits the searched physical address to the memory controller 510. The memory controller 510 transmits a data read command containing the physical address to the NAND memory 520. The NAND memory 520 senses data using the physical address in the data read command and when the NAND memory 520 has prepared the data, the memory controller 510 read the data and provides it to the host.

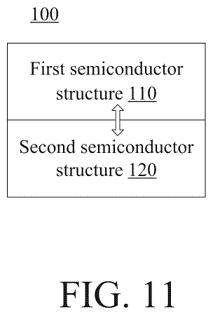

As shown in FIG. 11, the above-described memory 100 (DRAM memory) may include a first semiconductor structure 110 and a second semiconductor structure 120, the first semiconductor structure 110 being coupled with the second semiconductor structure 120. In some implementations, the first semiconductor structure 110 is formed on a first wafer and the second semiconductor structure 120 is formed on a second wafer. When the first wafer and the second wafer are completed respectively, the first wafer and the second wafer are bonded together by bonding process. In some examples, for the bonding process, the wafer surface is polished and cleaned and then undergoes plasma surface activation; the wafer after plasma activation is subjected to silica sol washing treatment in which large amount of oxhydryls carried on silica sol particles' surfaces will be rapidly absorbed on the wafer surface when contacting with the wafer surface since the silica sol particles have very high surface activity; and at the same time, particles of the silica sol may fill voids in microstructures of the wafer surface well. After heat treatment, the silica sol particles and the base are completed integrated, thereby reducing voids in microstructures. Finally, water molecules are removed by heat treatment under a certain temperature to form covalent bonds, realizing stable bonding.

In some examples, the memory array 200, word lines and bit lines as shown in FIG. 3 are formed in the first semiconductor structure 110. The peripheral circuit 300 as shown in FIG. 9 is formed in the second semiconductor structure 120, wherein the peripheral circuit 300 includes a plurality of word line drivers 310 corresponding to each memory block 211. The first semiconductor structure 110 and the second semiconductor structure 120 may be fabricated with different fabrication processes. In some examples, the first semiconductor structure 110 may be fabricated with established fabrication processes such as those of 22 nm, 28 nm or above to guarantee stability of the stored data. The second semiconductor structure 120 may be fabricated with advanced fabrication processes such as those of 14 nm, 10 nm or below to improve the speeds of reading/writing data.

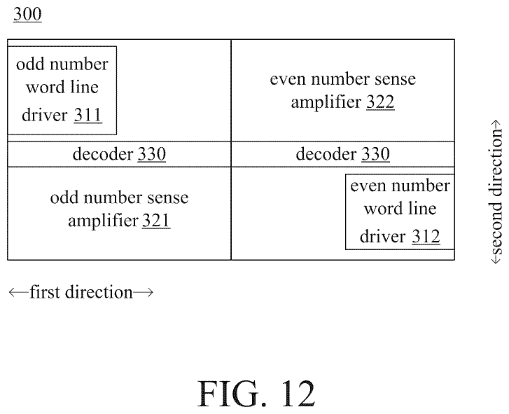

As shown in FIG. 12, in some implementations, the number of the word line drivers 310 is N, and the N word line drivers 310 may include a plurality of odd-numbered word line drivers 311 and a plurality of even-numbered word line drivers 312, and the sense amplifiers 320 include odd-numbered sense amplifiers 321 and even-numbered sense amplifiers 322. The plurality of odd-numbered word line drivers 311 are disposed on one side of the corresponding memory blocks 211 in the first direction, i.e., the length direction of the word line, and the plurality of even-numbered word line drivers 312 are disposed on the other side of the corresponding memory blocks 211 in the first direction, i.e., the length direction of the word line. The odd-numbered sense amplifiers 321 are disposed on one side of the corresponding memory blocks 211 in the second direction, i.e., the length direction of the bit line, and the even-numbered sense amplifiers 322 are disposed on the other side of the corresponding memory blocks 211 in the second direction, i.e., the length direction of the bit line. Decoders 330 are disposed between the plurality of odd-numbered word line drivers 311 and odd-numbered sense amplifiers 321, and between the plurality of even-numbered word line drivers 312 and even-numbered sense amplifiers 322 respectively.

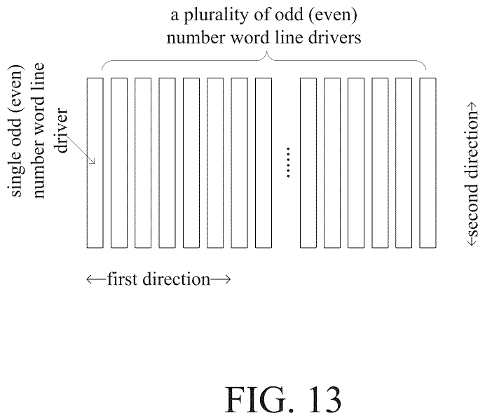

As shown in FIG. 13, in implementations of the present application, the plurality of transistors in the word line driver 310 are arranged in the channel width direction of the transistor, and the channel width direction of the transistor is perpendicular to the first direction (i.e., the length direction of the word line). The plurality of odd-numbered word line drivers 311 (even-numbered word line drivers 312) are arranged in the first direction (i.e., the length direction of the word line).

In some implementations, as shown in FIGS. 12 and 13, the plurality of odd-numbered word line drivers 311 (even-numbered word line drivers 312) are arranged into one row of odd-numbered word line drivers (one row of even-numbered word line drivers) in the first direction (i.e., the length direction of the word line).

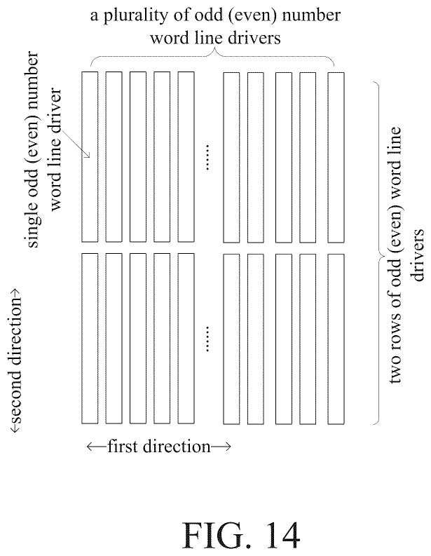

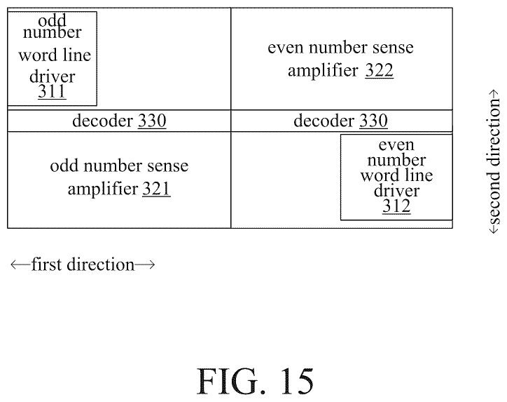

As shown in FIGS. 14 and 15, in order to balance the sizes of the N word line drivers 310 in the first direction (i.e., the length direction of the word line) and in the second direction (i.e., the length direction of the bit line), as shown in FIG. 14, in some other implementations, the plurality of odd-numbered word line drivers 311 (even-numbered word line drivers 312) are arranged into two rows of odd-numbered word line drivers (two rows of even-numbered word line drivers) in the first direction (i.e., the length direction of the word line), and the two rows of odd-numbered word line drivers (two rows of even-numbered word line drivers) are arranged in the second direction (i.e., the length direction of the bit line). As shown in FIG. 15, as compared to the layout shown in FIG. 12, applying the layout shown in FIG. 15 can make disposing positions for more word line drivers 310 closer to the ends of word lines, thereby even facilitating coupling between word line drivers 310 and word lines.

In implementations of the present application, the layout of the plurality of word line drivers 310 corresponding to each memory block 211 is re-designed such that the channel width direction of the transistor in the word line driver 310 is perpendicular to the first direction (i.e., the length direction of the word line), and the plurality of word line drivers 310 are arranged in the first direction (i.e., the length direction of the word line), thereby reducing the size of the plurality of word line drivers 310 in the second direction (i.e., the length direction of the bit line). That is, the implementations of the present application can reduce the size of the memory block 211 in the second direction (i.e., the length direction of the bit line) and in turn reduce the size of the memory 100. At the same time, it is possible to reduce the length of bit lines coupled with the memory block 211, reduce the coupling capacitance between bit lines and optimize the read/write performance of the memory 100.

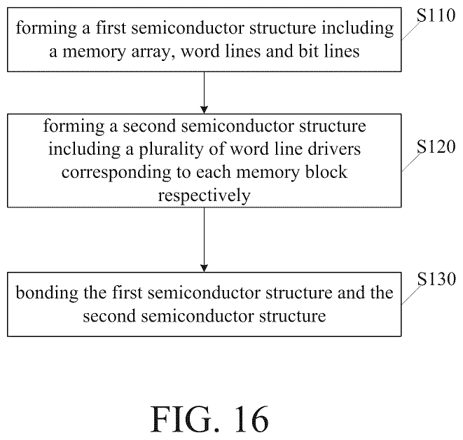

An implementation of the present application provides a forming method of a memory. As shown in FIG. 16, the forming method includes operation 110 to operation 130 as follows.

S110, forming a first semiconductor structure including a memory array, word lines and bit lines.

In some implementations, the first semiconductor structure 110 is formed on the first wafer, wherein the memory array 200 includes a plurality of memory banks 210 each including a plurality of memory blocks 211. The word lines and bit lines are coupled with memory blocks 211. The length direction of the word line is the first direction (i.e., the length direction of the word line). The length direction of the bit line is the second direction (i.e., the length direction of the bit line). The first direction is perpendicular to the second direction.

S120, forming a second semiconductor structure including a plurality of word line drivers corresponding to each memory block.

In some implementations, the second semiconductor structure 120 is formed on a second wafer. The word line driver 310 includes a plurality of transistors arranged in the channel width direction of the transistor. The channel width direction of the plurality of transistors in word line drivers 310 is perpendicular to the first direction (i.e., the length direction of the word line).

In some implementations, the number of the word line drivers 310 is N and the N word line drivers 310 are arranged in the first direction (i.e., the length direction of the word line). In some examples, the N word line drivers 310 are arranged into one row of word line drivers 310 in the first direction (i.e., the length direction of the word line). In some other examples, the N word line drivers 310 are arranged into two rows of word line drivers 310 in the first direction (i.e., the length direction of the word line), and the two rows of word line drivers 310 are arranged in the second direction (i.e., the length direction of the bit line).

In some implementations, the second semiconductor structure 120 further includes a decoder 330 and a sense amplifier 320 coupled with bit lines, wherein the word line drivers 310 include odd-numbered word line drivers 311 and even-numbered word line drivers 312, and the sense amplifiers 320 include odd-numbered sense amplifiers 321 and even-numbered sense amplifiers 322. The odd-numbered word line driver 311 is disposed on a side of a corresponding memory block 211 in the first direction, i.e., the length direction of the word line, and the even-numbered word line driver 312 is disposed on the other side of the corresponding memory block 211 in the first direction, i.e., the length direction of the word line. The odd-numbered sense amplifier 321 is disposed on a side of the corresponding memory block 211 in the second direction, i.e., the length direction of the bit line, and the even-numbered sense amplifier 322 is disposed on the other side of the corresponding memory block 211 in the second direction, i.e., the length direction of the bit line. Decoders 330 are disposed between the odd-numbered word line drivers 311 and the odd-numbered sense amplifiers 321, and between the even-numbered word line drivers 312 and the even-numbered sense amplifiers 322.

S130, bonding the first semiconductor structure and the second semiconductor structure.

In some implementations, the first semiconductor structure 110 and the second semiconductor structure 120 are bonded by bonding the first wafer and the second wafer. In some examples, a plurality of first semiconductor structures 110 are formed on the first wafer, and a plurality of second semiconductor structures 120 are formed on the second wafer. After the first wafer and the second wafer are bonded, the bonded first wafer and second wafer is cut to form a plurality of memories 100.

Examples of the present application provide a memory, a forming method of the memory and a memory system. The memory includes a first semiconductor structure and a second semiconductor structure, the first semiconductor structure being coupled with the second semiconductor structure. The first semiconductor structure includes a memory array, word lines and bit lines; wherein the memory array includes a plurality of memory banks each including a plurality of memory blocks; the word lines and bit lines are coupled with the memory blocks, a length direction of the word lines is a first direction, a length direction of the bit lines is a second direction, and the first direction is perpendicular to the second direction. The second semiconductor structure includes a plurality of word line drivers corresponding to each memory block respectively, the word line drivers being coupled with the word lines; the word line driver includes a plurality of transistors arranged in a channel width direction of the transistor. The channel width direction of the transistor is perpendicular to the first direction. In implementations of the present application, the layout of the plurality of word line drivers corresponding to each memory block respectively is re-designed such that the channel width direction of the transistor in the word line driver is perpendicular to the first direction (i.e., the length direction of the word line) and the plurality of word line drivers are arranged in the first direction (i.e., the length direction of the word line), thereby reducing the size of the plurality of word line drivers in the second direction (i.e., the length direction of the bit line). That is, the implementations of the present application can reduce the size of the memory block in the second direction (i.e., the length direction of the bit line) and in turn reduce the size of the memory. At the same time, the implementations of the present application can reduce the length of bit lines coupled with the memory block, reduce the coupling capacitance between bit lines and optimize the read/write performance of the memory.

Those skilled in the art can clearly understand that for convenient and concise description, in the above-described examples, there are focuses in the description of various examples, and a corresponding process in the above-described method examples may be referred to for a part not detailed in a certain example, which will not be described any more herein.

It should be understood that in the several examples provided in the present application, the provided memory, forming method of memory and memory system may be implemented in other ways. For example, the division of a module is only a logical function division and there may be other division manners upon practical implementation. For example, a plurality of units or components may be combined or integrated into another system, or some features may be omitted or not executed.

Those skilled in the art may realize that the modules and algorithm steps of examples described in examples disclosed herein may be implemented with electronic hardware, or combination of computer software and electronic hardware. Whether these functions are executed in hardware or software depends on particular applications of the technical scheme and the design constraints. Those skilled in the art can implement the described functions with different methods for each particular application, which will not be considered as beyond the scope of the present application.

What have been described above are only implementations of the present application. The scope of the present application is not limited thereto. Variations and substitutions that easily occur to any one skilled in the art in the technical scope disclosed by the present application should be encompassed in the scope of the present application. Therefore, the scope of the present application should be determined by the scope of the claims.

What is claimed is:

1. A memory device, comprising a first semiconductor structure and a second semiconductor structure coupled with the first semiconductor structure, wherein
the first semiconductor structure comprises a memory array, word lines and bit lines; wherein the memory array comprises memory banks each comprising memory blocks; and the word lines and the bit lines are coupled to the memory blocks, a length direction of the word lines is a first direction, and a length direction of the bit lines is a second direction perpendicular to the first direction; and
the second semiconductor structure comprises word line drivers corresponding to each memory block respectively, the word line drivers being coupled with the word lines; and the word line driver comprises transistors arranged in a third direction perpendicular to the first direction.

2. The memory device of claim 1, wherein the number of the word line drivers is N and the word line drivers are arranged in the first direction.

3. The memory device of claim 2, wherein the word line drivers are arranged in a row in the first direction.

4. The memory device of claim 2, wherein the word line drivers are arranged into two rows of word line drivers in the first direction, and the two rows of word line drivers are arranged in the second direction.

5. The memory device of claim 1, wherein the word line drivers comprise odd-numbered word line drivers and even-numbered word line drivers, wherein the odd-numbered word line driver is disposed on a side of a corresponding memory block in the first direction, and the even-numbered word line driver is disposed on another side of the corresponding memory block in the first direction.

6. The memory device of claim 5, wherein the second semiconductor structure further comprises decoders; and
a sum of lengths of the odd-numbered word line drivers and the decoders in the second direction is smaller than a length of the memory block in the second direction, and a sum of lengths of the even-numbered word line drivers and the decoders in the second direction is smaller than the length of the memory block in the second direction.

7. The memory device of claim 1, wherein the second semiconductor structure further comprises sense amplifiers coupled to the bit lines; and
the sense amplifiers comprise odd-numbered sense amplifiers and even-numbered sense amplifiers, wherein the odd-numbered sense amplifier is disposed on a side of a corresponding memory block in the second direction, and the even-numbered sense amplifier is disposed on another side of the corresponding memory block in the second direction.

8. The memory device of claim 1, wherein the first semiconductor structure and the second semiconductor structure are bonded.

9. A forming method of a memory device, comprising:
forming a first semiconductor structure, wherein the first semiconductor structure comprises a memory array, word lines and bit lines; wherein the memory array comprises memory banks each comprising memory blocks; the word lines and the bit lines are coupled to the memory blocks, a length direction of the word lines is a first direction, a length direction of the bit lines is a second direction, and the first direction is perpendicular to the second direction;
forming a second semiconductor structure, wherein the second semiconductor structure comprises word line drivers corresponding to each memory block respectively; the word line driver comprises transistors arranged in a third direction perpendicular to the first direction; and
bonding the first semiconductor structure and the second semiconductor structure.

10. The forming method of claim 9, wherein the number of the word line drivers is N and the word line drivers are arranged in the first direction.

11. The forming method of claim 10, wherein the word line drivers are arranged in a row of in the first direction.

12. The forming method of claim 10, wherein the word line drivers are arranged into two rows of word line drivers in the first direction, and the two rows of word line drivers are arranged in the second direction.

13. The forming method of claim 9, wherein the word line drivers comprise odd-numbered word line drivers and even-numbered word line drivers, wherein the odd-numbered word line driver is disposed on a side of a corresponding memory block in the first direction, and the even-numbered word line driver is disposed on another side of the corresponding memory block in the first direction.

14. The forming method of claim 13, wherein the second semiconductor structure further comprises decoders; and
a sum of lengths of the odd-numbered word line drivers and the decoders in the second direction is smaller than a length of the memory block in the second direction, and a sum of lengths of the even-numbered word line drivers and the decoders in the second direction is smaller than the length of the memory block in the second direction.

15. The forming method of claim 9, wherein the second semiconductor structure further comprises sense amplifiers coupled to the bit lines; and
the sense amplifiers comprise odd-numbered sense amplifiers and even-numbered sense amplifiers, wherein the odd-numbered sense amplifier is disposed on a side of a corresponding memory block in the second direction, and the even-numbered sense amplifier is disposed on another side of the corresponding memory block in the second direction.

16. The forming method of claim 9, wherein the first semiconductor structure is formed on a first wafer, and the second semiconductor structure is formed on a second wafer; and
bonding the first semiconductor structure and the second semiconductor structure further comprises:
bonding the first wafer and the second wafer and cutting the first wafer and the second wafer.

17. A memory system, comprising:
a memory controller; and
a memory device coupled with the memory controller, the memory device comprising:
a first semiconductor structure and a second semiconductor structure, the first semiconductor structure being coupled with the second semiconductor structure, wherein:
the first semiconductor structure comprises a memory array, word lines and bit lines;
wherein the memory array comprises memory banks each comprising memory blocks; and the word lines and the bit lines are coupled to the memory blocks, a length direction of the word lines is a first direction, and a length direction of the bit lines is a second direction perpendicular to the first direction; and
the second semiconductor structure comprises word line drivers corresponding to each memory block respectively, the word line drivers being coupled with the word lines; and the word line driver comprises transistors arranged in a third direction perpendicular to the first direction; and
wherein the memory controller is configured to control the memory.

18. The memory system of claim 17, wherein the number of the word line drivers is N and the word line drivers are arranged in the first direction.

19. The memory system of claim 17, wherein the word line drivers comprise odd-numbered word line drivers and even-numbered word line drivers, wherein the odd-numbered word line driver is disposed on a side of a corresponding memory block in the first direction, and the even-numbered word line driver is disposed on another side of the corresponding memory block in the first direction.

20. The memory system of claim 17, wherein the first semiconductor structure and the second semiconductor structure are bonded.
